(19) United States
(12) Patent Application Publication
(10) Pub. No.: US 2024/0121886 A1
(43) Pub. Date: Apr. 11, 2024

(54) WIRING BOARD

(71) Applicant: Nippon Telegraph and Telephone Corporation, Tokyo (JP)

(72) Inventors: Miwa Muto, Tokyo (JP); Hideaki Matsuzaki, Tokyo (JP)

(21) Appl. No.: 18/554,170

(22) PCT Filed: Apr. 13, 2021
(86) PCT No.: PCT/JP2021/015288

§ 371 Date: Oct. 5, 2023

(51) Int. Cl. H05K 1/02; H01P 3/00; H01P 3/08

(52) U.S. Cl. CPC H05K 1/0227; H01P 3/006; H01P 3/081; H01P 3/088

(57) ABSTRACT

A wiring board includes a dielectric substrate, a ground layer disposed on one surface of the dielectric substrate, a first conductor line and a first ground plane that are disposed apart from each other on the other surface opposing the one surface of the dielectric substrate, and a second conductor line disposed immediately below the first ground plane in the dielectric substrate.

### CROSS-REFERENCE TO RELATED APPLICATIONS

This application is a national phase entry of PCT Application No. PCT/JP2021/015288, filed on Apr. 13, 2021, which application is hereby incorporated herein by reference.

### TECHNICAL FIELD

The present invention relates to a wiring board including a high-frequency transmission line.

### BACKGROUND

In a wiring board (high-frequency transmission line substrate) including a high-frequency transmission line, electrical design such as characteristic impedance is important. For example, in the high-frequency transmission line substrate, electromagnetic and electromagnetic wave-like behaviors such as reflection and crosstalk propagating through a signal line are significant, and thus matching and reflection noise countermeasures are required. In particular, parallel running wirings inside a module are constituted of many adjacent wirings, and problems of wiring delay and crosstalk noise have become apparent.

In the high-frequency transmission line substrate, a microstrip line, a coplanar line, a grounded coplanar line, or the like is used as a wiring structure (transmission line structure) for propagating a high-speed high-frequency signal. For example, the microstrip line constitutes a transmission line by forming a ground layer of a planar conductor layer on one surface of a dielectric substrate and forming a strip-shaped line on the other surface. The characteristic impedance of these lines is determined by a width and a thickness of the signal line, a dielectric constant of the dielectric substrate, a thickness, and a geometric dimension of a gap between the signal line and a ground pattern.

Further, in order to reduce the cost of the high-frequency transmission line substrate, it is necessary to integrate the parallel running wirings at a high density. However, in a case where the parallel running wirings are integrated at a high density, a distance between lines becomes short, and a problem such as crosstalk between transmission lines is significant.

Therefore, in a wiring board connected to a semiconductor high-frequency module, a parallel running wiring structure that maintains a high-frequency characteristic and enables high density signal transmission is demanded.

### CITATION LIST

### Patent Literature

Patent Literature 1: JP 2005-101587 A.

### SUMMARY

### Technical Problem

As described above, when signals are transmitted at a high density, signal lines need to be arranged at a high density. However, when the distance between the signal lines decreases, crosstalk noise between wirings increases, and thus it is difficult to transmit a signal while maintaining a high frequency characteristic.

Specifically, when a signal pulse is transmitted by one signal line, the crosstalk noise between wirings is generated by displacement of electrons in the other signal line. When the interval between the signal lines decreases, the displacement amount of the electrons in the other signal line increases, and the crosstalk noise increases.

Therefore, it is difficult to achieve the parallel running wiring structure that maintains a high-frequency characteristic and enables high density signal transmission.

Further, when the distance between the signal lines decreases, the distance between the signal lines and the ground layer, the ground plane, or the like decreases, and in particular, when the signal line width is fixed, it has been difficult to set a desired characteristic impedance.

For example, Patent Literature 1 discloses a high-density mounting technique for suppressing crosstalk. However, since signals that can be transmitted by this technology are limited to differential signals, there is a problem that the technology cannot be applied to various transmission systems.

### Solution to Problem

In order to solve the above-described problem, a wiring board according to embodiments of the present invention includes a dielectric substrate, a ground layer disposed on one surface of the dielectric substrate, a first conductor line and a first ground plane disposed apart from each other on another surface opposing the one surface of the dielectric substrate, and a second conductor line disposed immediately below the first ground plane in the dielectric substrate.

### Advantageous Effects of Embodiments of the Invention

According to embodiments of the present invention, it is possible to provide a wiring board capable of suppressing crosstalk and of being applied to various transmission methods.

### BRIEF DESCRIPTION OF THE DRAWINGS

FIG. 1A is a schematic top view of a wiring board according to a first embodiment of the present invention.

FIG. 1B is a schematic cross-sectional view taken along a line IB-IB′ of the wiring board according to the first embodiment of the present invention.

FIG. 1C is a schematic cross-sectional view taken along a line IC-IC′ of the wiring board according to the first embodiment of the present invention.

FIG. 2A is a schematic view of a model used for calculation of characteristics of the wiring board according to the first embodiment of the present invention.

FIG. 2B is a schematic view of a model used for calculation of characteristics of the wiring board according to the first embodiment of the present invention.

FIG. 3A is a schematic view of a model used for calculation of characteristics of a conventional wiring board.

FIG. 3B is a schematic view of a model used for calculation of characteristics of the conventional wiring board.

FIG. 4A is a diagram illustrating an effect of the wiring board according to the first embodiment of the present invention.

FIG. 4B is a diagram illustrating an effect of the wiring board according to the first embodiment of the present invention.

FIG. 5A is a schematic top view of a wiring board according to a second embodiment of the present invention.

FIG. 5B is a schematic cross-sectional view taken along a line VB-VB′ of the wiring board according to the second embodiment of the present invention.

FIG. 5C is a schematic cross-sectional view taken along a line VC-VC′ of the wiring board according to the second embodiment of the present invention.

FIG. 6A is a schematic view of a model used for calculation of characteristics of the wiring board according to the second embodiment of the present invention.

FIG. 6B is a schematic view of a model used for calculation of characteristics of the wiring board according to the second embodiment of the present invention.

FIG. 7A is a schematic view of a model used for calculation of characteristics of a conventional wiring board.

FIG. 7B is a schematic view of a model used for calculation of characteristics of a conventional wiring board.

FIG. 8A is a view illustrating an effect of the wiring board according to the second embodiment of the present invention.

FIG. 8B is a view illustrating an effect of the wiring board according to the second embodiment of the present invention.

### DETAILED DESCRIPTION OF ILLUSTRATIVE EMBODIMENTS

### First Embodiment

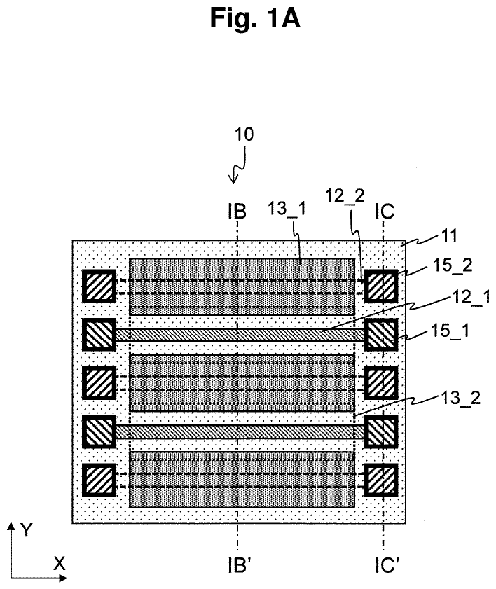

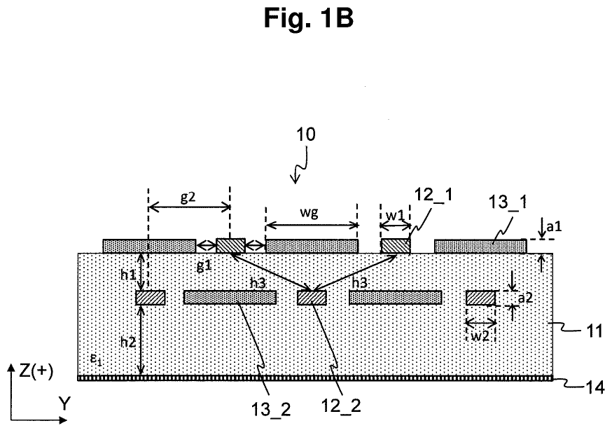

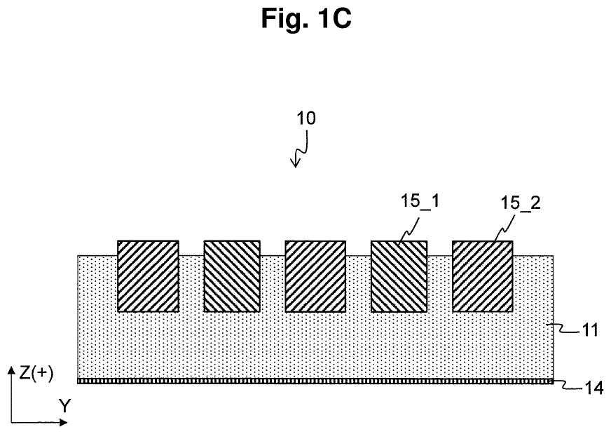

A wiring board according to a first embodiment of the present invention will be described with reference to FIGS. 1A to 4B.

### Configuration of Wiring Board

FIG. 1A is a schematic top view of a wiring board 10 according to the present embodiment. Further, FIGS. 1B and 1C illustrate schematic sectional views taken along lines IB-IB′ and IC-IC′ in FIG. 1A, respectively. Hereinafter, an XY plane in FIGS. 1A to 1C is a horizontal plane, a Z direction is a vertical direction, a Z(+) direction is an upward direction, and an opposite direction thereof is a downward direction.

As illustrated in FIGS. 1A and 1B, the wiring board 10 includes a dielectric substrate 11 and a ground layer 14 on a lower surface (one surface) of the dielectric substrate 11, and includes a first conductor line (signal line) 12_1 constituted of a strip-shaped conductor, a first ground plane 13_1, a first electrode 15_1, and a second electrode 15_2 on an upper surface (other surface) opposing the lower surface of the dielectric substrate 11.

Further, on the same horizontal plane in the dielectric substrate 11, a second conductor line (signal line) 12_2 arranged at a position immediately below the first ground plane 13_1 and a second ground plane 13_2 arranged at a position immediately below the first conductor line 12_1 are provided.

Here, benzocyclobutene (BCB) or the like is used for the dielectric substrate 11. Further, a conductor member such as Au is used for the first conductor line 12_1, the second conductor line 12_2, the first ground plane 13_1, the second ground plane 13_2, the first electrode 15_1, and the second electrode 15_2.

The first electrode 15_1 is connected to the first conductor line 12_1, and the second electrode 15_2 is connected to the second conductor line 12_2. Here, as illustrated in FIG. 1C, an example has been described in which, in order to suppress the influence of the electrode capacitance in measurement (to be described later) by making the electrode capacitance of the first conductor line 12_1 and the electrode capacitance of the second conductor line 12_2 the same, the first electrode 15_1 and the second electrode 15_2 are formed up to the inside of the dielectric substrate 11, but the first electrode 15_1 may be formed only on the surface and connected to the first conductor line 12_1.

As described above, in the wiring board 10, the first conductor line 12_1 of the strip-shaped conductor arranged on the other surface (upper surface) and the first ground plane 13_1 form a coplanar line.

Furthermore, in the same plane parallel to the upper surface in the dielectric substrate 11, the strip-shaped second conductor line 12_2 arranged immediately below the first ground plane 13_1 and the second ground plane 13_2 arranged immediately below the first conductor line 12_1 form a coplanar line.

In this configuration, the coplanar line on the other surface (upper surface) and the second ground plane 13_2 in the dielectric substrate 11 form a grounded coplanar line. Similarly, the coplanar line in the dielectric substrate 11 and the first ground plane 13_1 on the other surface (upper surface) form a grounded coplanar line.

In this manner, the grounded coplanar lines having the second ground plane 13_2 as the ground layer 14 and the grounded coplanar lines having the first ground plane 13_1 as the ground layer 14 are alternately arranged.

In the wiring board 10, crosstalk noise can be reduced by making a distance (hereinafter referred to as an “inter-line distance”) h3 between the first conductor line 12_1 and the second conductor line 12_2 larger than a substantial inter-line distance (hereinafter referred to as a “substantial inter-line distance”) g2 as viewed from above (in the horizontal direction) (g2<h3).

Furthermore, by making a distance g1 between the first conductor line 12_1 and the first ground plane 13_1 and a distance between the second conductor line 12_2 and the second ground plane 13_2 smaller than the inter-line distance h3 (g1<h3), the electric field generated between the first conductor line 12_1 and the first ground plane 13_1 and between the second conductor line 12_2 and the second ground plane 13_2 increases.

Further, by making a distance h1 between the first conductor line 12_1 and the second ground plane 13_2 and a distance h1 between the second conductor line 12_2 and the first ground plane 13_1 smaller than the inter-line distance h3 (h1<h3), the electric field generated between the first conductor line 12_1 and the second ground plane 13_2 and between the second conductor line 12_2 and the first ground plane 13_1 increases.

Consequently, by the ground plane disposed closest to the conductor line in the same plane as the conductor line and the ground plane disposed immediately below or immediately above the conductor line, the electric field generated from one conductor line is deflected in the direction in which the ground plane is disposed, so that the electric field transmitted from the one conductor line in the direction of the other conductor line is suppressed. Therefore, the crosstalk noise can be reduced.

Thus, it is possible to achieve the wiring board 10 having parallel running wirings in which the wiring area can be reduced and the crosstalk noise between the wirings can be reduced.

Further, in the ground plane disposed closest to the conductor line in the same plane as the conductor line and the ground plane disposed immediately below or immediately above the conductor line, by adjusting the distance between the conductor line and the ground plane, the degree of freedom in setting the characteristic impedance of the line can be higher than that of a normal coplanar line or microstrip line.

Further, the present technology can be applied to various transmission systems, and can be put into practical use and reduced in cost.

### Effects of Wiring Board

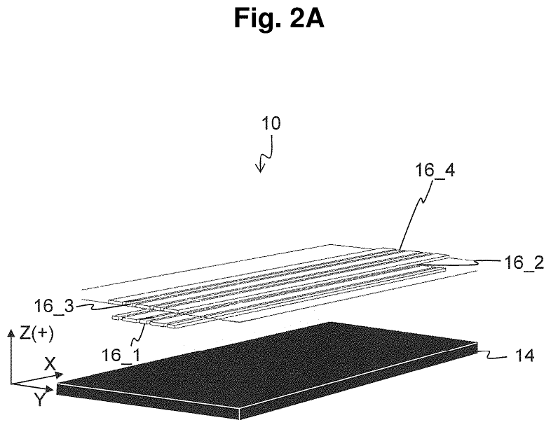

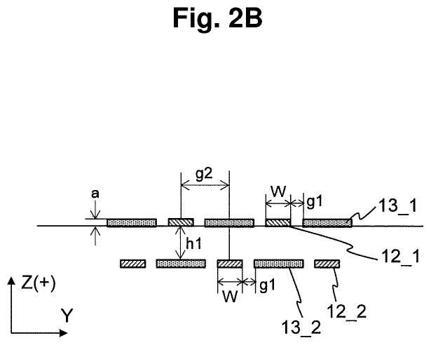

Effects of the wiring board 10 according to the present embodiment will be described below with reference to FIGS. 2A to 4B.

The amount of crosstalk of the wiring board 10 according to the present embodiment is simulated and compared with a conventional wiring board 10′.

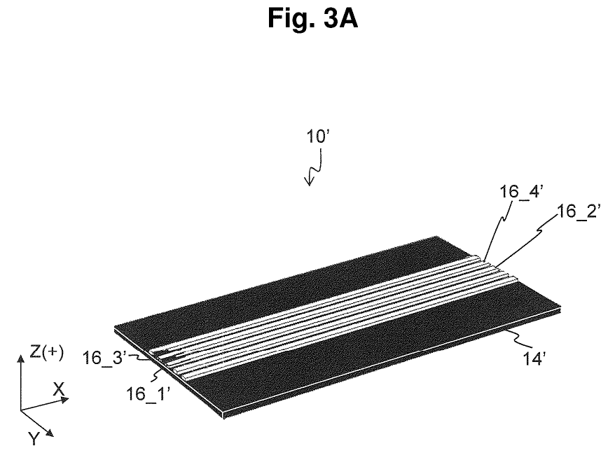

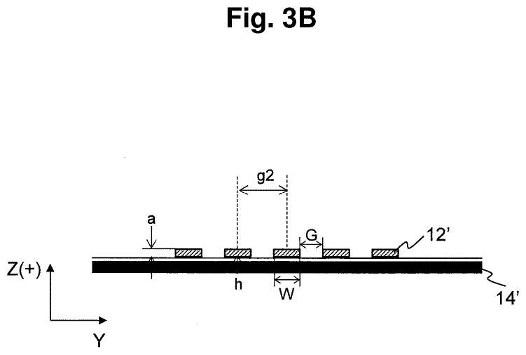

FIGS. 2A and 2B illustrate a schematic view of the wiring board 10 and a schematic cross-sectional view of a wiring structure according to the present embodiment used for simulation, respectively. Further, FIGS. 3A and 3B illustrate a schematic view of the conventional wiring board 10′ and a schematic cross-sectional view of a wiring structure used for simulation, respectively.

For the simulation, an electromagnetic field simulator “Sonnet-EM” (manufactured by Sonnet Giken) is used.

In the wiring board 10 used for the simulation, Au metal is used for the strip-shaped first conductor line 12_1, the strip-shaped second conductor line 12_2, the first ground plane 13_1, the second ground plane 13_2, and the ground layer 14. Further, a benzocyclobutene (BCB) substrate (εr=2.7) is used for the dielectric substrate 11. Further, a parallel running wiring of a microstrip line having a line length of 300 μm is assumed.

Further, in order to equalize the characteristic impedance and simplify the calculation, a BCB layer is formed on the first conductor line 12_1 and the first ground plane 13_1, and the periphery is covered with the BCB similarly to the second conductor line 12_2. Furthermore, each of the number of conductor lines and the number of ground planes is five.

Further, the substantial inter-line distance g2 is 12 μm, the thicknesses of the first conductor line 12_1 and the second conductor line 12_2 are 2 μm, the thicknesses of the first ground plane 13_1 and the second ground plane 13_2 are 2 μm, and the characteristic impedance is 50Ω.

As illustrated in FIGS. 2A and 2B, a configuration of the wiring board 10 according to the present embodiment is such that a width W1 of the first conductor line 12_1=6 μm, a width W2 of the second conductor line 12_2=6 μm, the distance g1 between the first conductor line 12_1 and the first ground plane 13_1=3 μm, and the distance h1 between the second conductor line 12_2 and the first ground plane 13_1=8 μm.

As illustrated in FIGS. 3A and 3B, a configuration of the conventional wiring board 10′ is such that a width W of a line 12′=6 μm, an inter-line distance G=6 μm, and a distance h between the line 12′ and a ground layer 14′=4 μm.

By calculating results of S parameters between ports illustrated in FIGS. 2B and 3B, the amount of crosstalk can be directly evaluated. For example, S31 is a ratio between a voltage of a signal supplied to the first port and a voltage output to the third port, and is referred to as backward (near end) crosstalk. Further, S41 is a ratio between the voltage of the signal supplied to the first port and a voltage output to the fourth port, and is referred to as forward (far end) crosstalk.

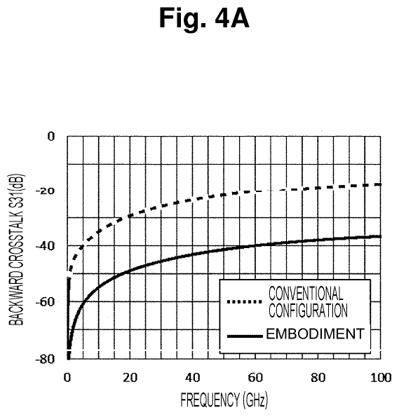

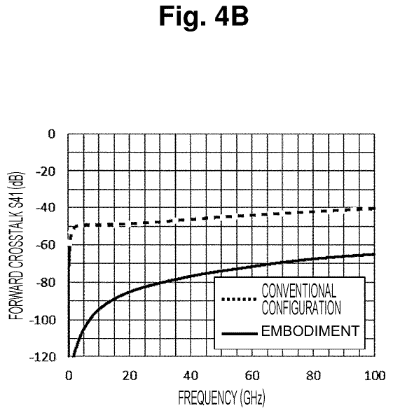

FIGS. 4A and 4B are simulation results of S31 (backward crosstalk) and S41 (forward crosstalk), respectively. Here, a decibel display is used for easy comparison.

In S31 (backward crosstalk), the crosstalk of the wiring board 10 is reduced in a range of more than 0 dB and 20 dB or less in a wide range of more than 0 GHz and 100 GHz or less as compared with the conventional wiring board 10′.

Further, in S41 (forward crosstalk), the crosstalk of the wiring board 10 is reduced in a range of 25 dB or more and 60 dB or less in the wide range of more than 0 GHz and 100 GHz or less as compared with the conventional wiring board 10′.

With the wiring board of the present embodiment, the crosstalk noise can be reduced by making the inter-line distance larger than the substantial inter-line distance as viewed from above (in the horizontal direction). Further, by making the distance between the line and the ground plane smaller than that between the lines, it is possible to further reduce the crosstalk noise.

As described above, with the wiring board of the present embodiment, the wiring density can be improved, the crosstalk noise between the wirings can be reduced, and the wiring board having the parallel running wirings applicable to high-density mounting can be achieved.

### Second Embodiment

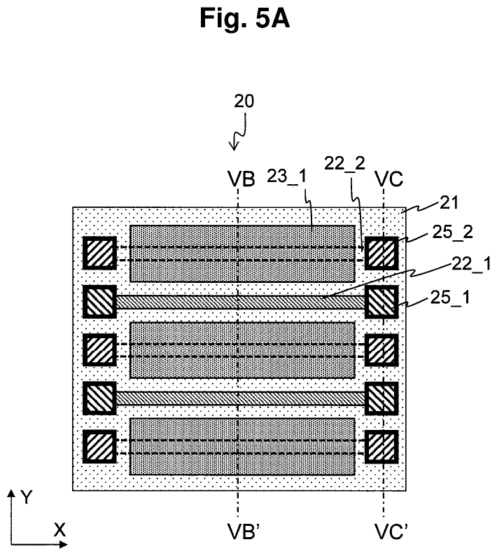

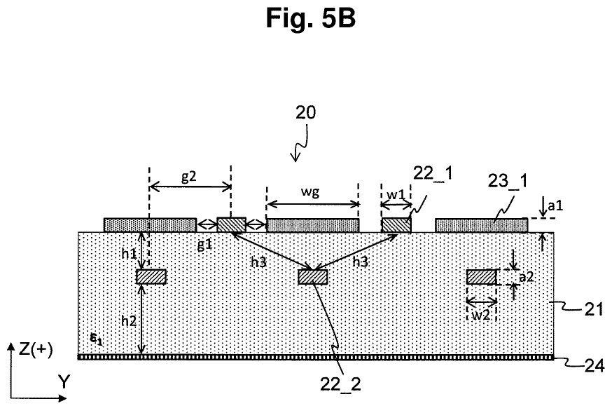

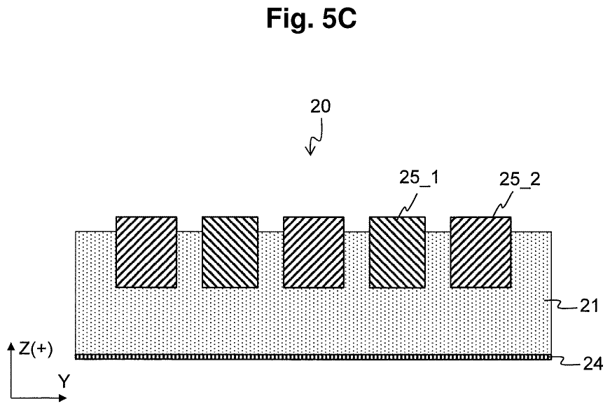

A wiring board according to a second embodiment of the present invention will be described with reference to FIGS. 5A to 5C.

### Configuration of Wiring Board

FIG. 5A is a schematic top view of a wiring board 20 according to the present embodiment. Further, FIGS. 5B and 5C are schematic sectional views taken along lines VB-VB′ and VC-VC′ in FIG. 5A, respectively.

As illustrated in FIGS. 5A and 5B, the wiring board 20 includes a dielectric substrate 21, a first conductor line 22_1 constituted of a strip-shaped conductor on an upper surface of the dielectric substrate 21, a first ground plane 23_1, a first electrode 25_1, and a second electrode 25_2, and includes a ground layer 24 on a lower surface (bottom surface) of the dielectric substrate 21.

Further, a second conductor line 22_2 is arranged at a position immediately below the first ground plane 23_1 on the same horizontal plane in the dielectric substrate 21.

Here, benzocyclobutene (BCB) or the like is used for the dielectric substrate 21. Further, a conductor member such as Au is used for the first conductor line 221, the second conductor line 222, the first ground plane 23_1, a second ground plane 23_2, the first electrode 25_1, and the second electrode 25_2.

The first electrode 25_1 is connected to the first conductor line 22_1, and the second electrode 25_2 is connected to the second conductor line 22_2. Here, as illustrated in FIG. 5C, an example has been described in which, in order to suppress the influence of the electrode capacitance in measurement (to be described later) by making the electrode capacitance of the first conductor line 22_1 and the electrode capacitance of the second conductor line 22_2 the same, the first electrode 25_1 and the second electrode 25_2 are formed up to the inside of the dielectric substrate 21, but the first electrode 25_1 may be formed only on the surface and connected to the first conductor line 22_1.

As described above, the wiring board 20 includes the dielectric substrate 21 (dielectric constant ε1), the ground layer 14 provided on one surface (bottom surface) of the dielectric substrate 21, and the coplanar line constituted of the first conductor line 22_1 of the strip-shaped conductor and the first ground plane 23_1 on the other surface (top surface).

Furthermore, the strip-shaped second conductor line 22_2 disposed immediately below the first ground plane 23_1 is provided in the same plane parallel to the upper surface in the dielectric substrate 21.

As described above, in the wiring board 20, the coplanar lines and the strip-shaped conductor lines (microstrip lines) are alternately arranged.

In the wiring board 20, the crosstalk noise can be reduced by making the inter-line distance h3 larger than the substantial inter-line distance g2 (g2<h3).

Furthermore, by making the distance g1 between the first conductor line 22_1 and the first ground plane 23_1 smaller than the inter-line distance h3 (g1<h3), the electric field generated between the first conductor line 22_1 and the first ground plane 23_1 increases.

Further, by making the distance h1 between the second conductor line 22_2 and the first ground plane 23_1 smaller than the inter-line distance h3 (h1<h3), the electric field generated between the second conductor line 22_2 and the first ground plane 23_1 increases.

Consequently, by the ground plane disposed closest to the conductor line in the same plane as the conductor line and the ground plane disposed immediately above the conductor line, the electric field generated from one conductor line is deflected in the direction in which the ground plane is disposed, so that the electric field transmitted from the one conductor line in the direction of the other conductor line is suppressed. Therefore, the crosstalk noise can be reduced.

Thus, it is possible to achieve the wiring board 20 having parallel running wirings in which the wiring area can be reduced and the crosstalk noise between the wirings can be reduced.

Further, in the ground plane disposed closest to the conductor line in the same plane as the conductor line and the ground plane disposed immediately above the conductor line, by adjusting the distance between the conductor line and the ground plane, the degree of freedom in setting the characteristic impedance of the line can be higher than that of a normal coplanar line or microstrip line.

Further, the present technology can be applied to various transmission systems, and can be put into practical use and reduced in cost.

### Effects of Wiring Board

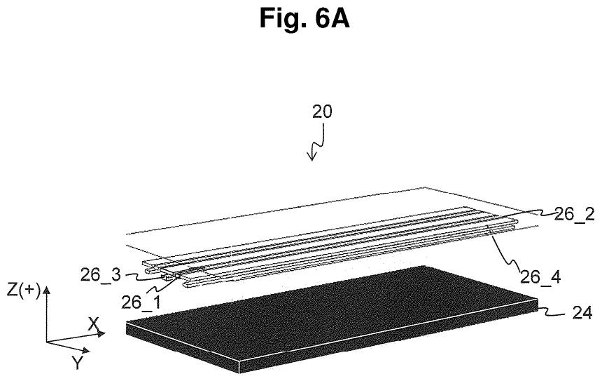

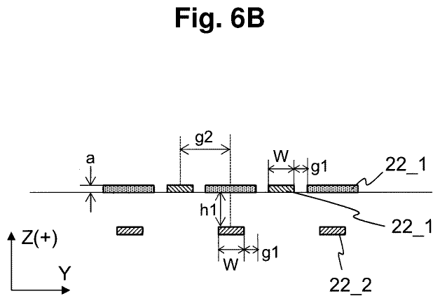

Effects of the wiring board 20 according to the present embodiment will be described below with reference to FIGS. 6A to 8B.

As in the first embodiment, the amount of crosstalk of the wiring board 20 according to the present embodiment is simulated and compared with a conventional wiring board 20′.

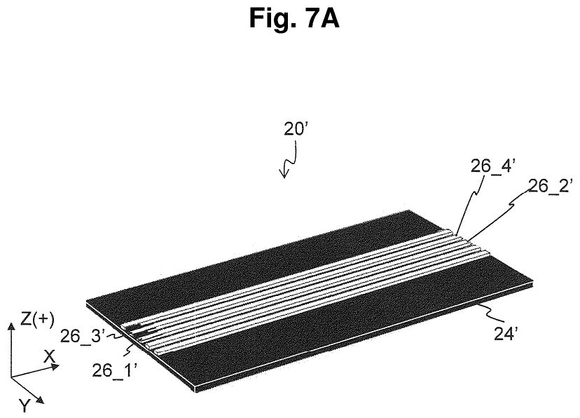

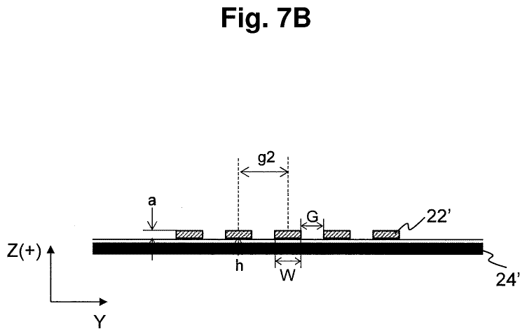

FIGS. 6A and 6B are a schematic view of the wiring board 20 and a schematic cross-sectional view of the wiring structure according to the present embodiment used for simulation, respectively. Further, FIGS. 7A and 7B illustrate a schematic view of the conventional wiring board 20′ and a schematic cross-sectional view of a wiring structure used for simulation, respectively.

As illustrated in FIGS. 6A and 6B, a configuration of the wiring board 20 according to the present embodiment is such that the width W1 of the first conductor line 22_1=6 μm, the width W2 of the second conductor line 22_2=6 μm, the distance g1 between the first conductor line 22_1 and the first ground plane 23_1=2.5 μm, and the distance h1 between the second conductor line 22_2 and the first ground plane 23_1=3 μm.

As illustrated in FIGS. 7A and 7B, a configuration of the conventional wiring board 20′ is such that, as in the first embodiment, a width W of a line 22′=6 μm, an inter-line distance G=6 μm, and a distance h between the line 22′ and a ground layer 24′=4 μm.

The configurations other than the above are the same as those of the first embodiment, and the characteristic impedance is 50 n.

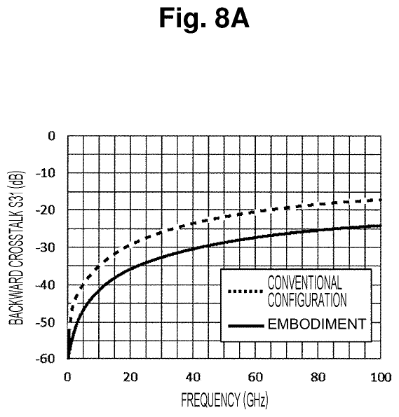

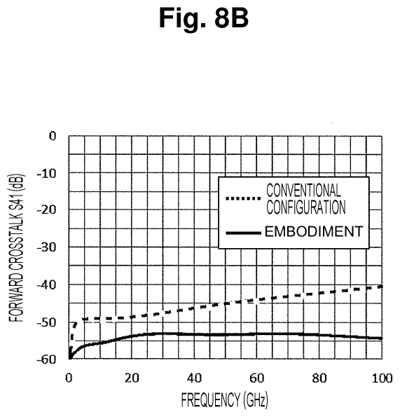

FIGS. 8A and 8B are simulation results of S31 (backward crosstalk) and S41 (forward crosstalk), respectively. Here, a decibel display is used for easy comparison.

In S31 (backward crosstalk), the crosstalk of the wiring board 20 is reduced in a range of more than 0 dB and 8 dB or less in the wide range of more than 0 GHz and 100 GHz or less as compared with the conventional wiring board 20′.

Further, in S41 (forward crosstalk), the crosstalk of the wiring board 20 is reduced in a range of more than 0 dB and 15 dB or less in the wide range of more than 0 GHz and 100 GHz or less as compared with the conventional wiring board 20′.

With the wiring board of the present embodiment, the crosstalk noise can be reduced by making the inter-line distance larger than the substantial inter-line distance as viewed from above (in the horizontal direction). Further, by making the distance between the line and the ground plane smaller than that between the lines, it is possible to further reduce the crosstalk noise.

As described above, with the wiring board according to the present embodiment, the crosstalk noise can be reduced by alternately arranging the microstrip lines and the coplanar lines even in the configuration in which the ground plane is not provided in the dielectric substrate and the grounded coplanar lines are not formed.

As described above, with the wiring board according to the present embodiment, it is possible to achieve a wiring board having parallel running wirings applicable to high-density mounting, in which the microstrip lines and the coplanar lines are alternately arranged at a high density, the wiring density can be improved, and crosstalk noise between the wirings can be reduced.

In an embodiment of the present invention, an example in which the number of signal lines (parallel running lines) and the number of ground planes are five has been described, but the present invention is not limited thereto, and it is only required to use a plurality of signal lines (parallel running lines).

In an embodiment of the present invention, an example in which the characteristic impedances of the first conductor line and the second conductor line are equal to each other has been described, but different characteristic impedances may be set for the first conductor line and the second conductor line.

Further, similar effects are also obtained in a configuration in which the first embodiment and the second embodiment are arbitrarily combined.

In an embodiment of the present invention, examples of the structure, the dimensions, the materials, and the like of each component have been described in the configuration of the wiring board and the like, but the present invention is not limited thereto. The wiring board is only required to exhibit its functions and achieve effects.

### INDUSTRIAL APPLICABILITY

The embodiments of the present invention can be applied to a semiconductor high-frequency module and a high-frequency transmission line substrate.

1.-6. (canceled)

7. A wiring board comprising:
a dielectric substrate;
a ground layer disposed on a first surface of the dielectric substrate;
a first conductor line and a first ground plane disposed apart from each other on a second surface of the dielectric substrate, the second surface being opposite the first surface; and
a second conductor line disposed immediately below the first ground plane in the dielectric substrate.

8. The wiring board according to claim 7, wherein only the second conductor line is provided in a plane parallel to the first surface in the dielectric substrate.

9. The wiring board according to claim 7, further comprising a second ground plane disposed immediately below the first conductor line in a plane parallel to the first surface in the dielectric substrate.

10. The wiring board according to claim 9, wherein a distance between the first conductor line and the second conductor line in a side view is larger than a substantial distance between a center of the first conductor line and a center of the second conductor line as viewed from above.

11. The wiring board according to claim 9, wherein a distance between the first conductor line and the first ground plane is smaller than a distance between the first conductor line and the second conductor line.

12. The wiring board according to claim 9, wherein a distance between the second conductor line and the first ground plane is smaller than a distance between the first conductor line and the second conductor line.

13. The wiring board according to claim 7, wherein a distance between the first conductor line and the second conductor line in a side view is larger than a substantial distance between a center of the first conductor line and a center of the second conductor line as viewed from above.

14. The wiring board according to claim 7, wherein a distance between the first conductor line and the first ground plane is smaller than a distance between the first conductor line and the second conductor line.

15. The wiring board according to claim 7, wherein a distance between the second conductor line and the first ground plane is smaller than a distance between the first conductor line and the second conductor line.

16. A method of forming a wiring board, the method comprising:
disposing a ground layer on a first surface of a dielectric substrate;
disposing a first conductor line and a first ground plane apart from each other on a second surface of the dielectric substrate, the second surface being opposite the first surface; and
disposing a second conductor line immediately below the first ground plane in the dielectric substrate.

17. The method according to claim 16, wherein only the second conductor line is provided in a plane parallel to the first surface in the dielectric substrate.

18. The method according to claim 16, further comprising disposing a second ground plane immediately below the first conductor line in a plane parallel to the first surface in the dielectric substrate.

19. The method according to claim 18, wherein a distance between the first conductor line and the second conductor line in a side view is larger than a substantial distance between a center of the first conductor line and a center of the second conductor line as viewed from above.

20. The method according to claim 18, wherein a distance between the first conductor line and the first ground plane is smaller than a distance between the first conductor line and the second conductor line.

21. The method according to claim 18, wherein a distance between the second conductor line and the first ground plane is smaller than a distance between the first conductor line and the second conductor line.

22. The method according to claim 16, wherein a distance between the first conductor line and the second conductor line in a side view is larger than a substantial distance between a center of the first conductor line and a center of the second conductor line as viewed from above.

23. The method according to claim 16, wherein a distance between the first conductor line and the first ground plane is smaller than a distance between the first conductor line and the second conductor line.

24. The method according to claim 16, wherein a distance between the second conductor line and the first ground plane is smaller than a distance between the first conductor line and the second conductor line.
